(19) United States
(12) Patent Application Publication
(10) Pub. No.: US 2019/0363233 A1
(43) Pub. Date: Nov. 28, 2019

(54) SEMICONDUCTOR LIGHT EMITTING APPARATUS HAVING MULTIPLE CONDUCTIVE BONDING LAYER ELEMENTS AND ITS MANUFACTURING METHOD

(71) Applicant: STANLEY ELECTRIC CO., LTD., Tokyo (JP)

(72) Inventor: Kazuhisa SHINNO, Tokyo (JP)

(21) Appl. No.: 16/410,881

(22) Filed: May 13, 2019

(30) Foreign Application Priority Data
May 24, 2018 (JP) 2018-099340

(51) Int. Cl. H01L 33/62; H01L 33/36

(52) U.S. Cl. CPC H01L 33/62; H01L 2933/0066; H01L 2933/0016; H01L 33/36

(57) ABSTRACT

A semiconductor light emitting apparatus includes a semiconductor light emitting element having a first electrode and a second electrode; a substrate having first and second wiring pattern layers electrically-connected to the first and second electrodes, respectively, and multiple conductive bonding layer elements provided between the first electrode and the first wiring pattern layer and/or between the second electrode and the second wiring pattern layer.

This application claims the priority benefit under 35 U.S.C. § 119 to Japanese Patent Application No. JP2018-099340 filed on May 24, 2018, which disclosure is hereby incorporated in its entirety by reference.

### BACKGROUND

### Field

The presently disclosed subject matter relates to a semiconductor light emitting apparatus having a semiconductor light emitting element mounted on a substrate and its manufacturing method.

### Description of the Related Art

Generally, in a semiconductor light emitting apparatus, a light emitting diode (LED) element is bonded by a high heat-dissipating AuSn eutectic bonding layer to a submount substrate.

A prior art method for manufacturing a semiconductor light emitting apparatus will be explained now with reference to FIGS. 1A, 1B, 2A, 2B, 3A and 3B.

First, referring to FIG. 1A and FIG. 1B which is a cross-sectional view taken along the line BB in FIG. 1A, an LED element 1 has slender p-side electrodes 11-1, 11-2, . . . , 11-6 electrically connected to a p-type semiconductor region (not shown) and a slender n-side electrode 12 electrically-connected to an n-type semiconductor region (not shown). In this case, each of the electrodes 11-1, 11-2, . . . , 11-6 and 12 viewed from the top has a rectangular shape with a short side and a long side twice or more as long as the short side. Thus, the heat resistance can be decreased and the fluctuation of a forward voltage can be suppressed. Also, since the p-side electrodes 11-1, 11-2, . . . , 11-6 are broadly spread on the bottom of the LED element 1, currents from the p-side electrodes 11-1, 11-2, . . . , 11-6 can be spread through an entire active region (not shown) within the LED element 1 to the n-side electrode 12, which can improve the light emitting efficiency and make the light emitting distribution uniform. Note that bonding layers (not shown) including an uppermost Au layer are formed on the p-side electrodes 11-1, 11-2, . . . , 11-6 and the n-side electrode 12 by a plating process or a sputtering process.

On the other hand, referring to FIG. 2A and FIG. 2B which is a cross-sectional view taken along the line B-B in FIG. 2A, a submount substrate 2 made of AlN, for example, has a p-side wiring pattern layer 21 and an n-side wiring pattern layer 22. The p-side wiring pattern layer 21 has AuSn layers 31-1, 31-2, . . . , 31-6 corresponding to the p-side electrodes 11-1, 11-2, . . . , 11-6, respectively, of the LED element 1, and the n-side wiring pattern layer 22 has an AuSn layer 32 corresponding to the n-side electrode 12 of the LED element 1. Note that bonding layers (not shown) including an uppermost Au layer are formed on the p-side wiring pattern layer 21 and the n-side wiring pattern layer 22, and pads (not shown) are formed thereon.

Finally, referring to FIG. 3A and FIG. 3B which is a cross-sectional view taken along the line B-B in FIG. 3A, the LED element 1 of FIGS. 1A and 1B is faced down in a thermal-pressuring process on the submount substrate 2 of FIGS. 2A and 2B, so that the uppermost Au layers of the AuSn layer 31-1, 31-2, . . . , 31-6 and 32 of the submount substrate 2 are eutectic with the uppermost Au layers of the p-side electrodes 11-1, 11-2, . . . , 11-6 and the n-side electrode 12 of the LED element 1 to form AuSn eutectic bonding layer 31′-1, 31′-2, . . . , 31′-6 and 32′. As a result, the p-side electrodes 11-1, 11-2, . . . , 11-6 of the LED element 1 are electrically connected to the p-side wiring pattern layer 21 of the submount substrate 2, and the n-side electrode 12 of the LED element 1 is electrically connected to the n-side wiring pattern layer 22 of the submount substrate 2. Thus, the LED element 1 is bonded by the AuSn eutectic bonding layer 31′-1, 31′-2, . . . , 31′-6 and 32′ to the submount substrate 2, completing a semiconductor light emitting apparatus 3.

In the semiconductor light emitting apparatus 3 of FIGS. 3A and 3B, however, the AuSn eutectic bonding layer 31′-1, 31′-2, . . . , 31′-6 and 32′ has the following bonding defects.

The AuSn layers 31-1, 31-2, . . . , 31-6 and 32 of FIGS. 2A and 2B are usually formed by a liftoff process. That is, as illustrated in FIG. 4A, a photoresist pattern 30-1 for forming the AuSn layers 31-1, 31-2, . . . , 31-6 and 32 is formed by a photolithography process on a submount substrate 2 (the p-side wiring pattern layer 21), and then, an AuSn layer 30-2 is deposited on the entire surface by a sputtering process or an evaporating process. Then, as illustrated in FIG. 4B, the photoresist pattern layer 30-1 is removed to form the AuSn layers 31-1, 31-2, . . . , 31-6 and 32. In this case, however, when the photoresist pattern layer 30-1 is removed to rupture the AuSn layer 30-2, burrs BR would be created on the edges of the AuSn layers 31-1, 31-2, . . . , 31-6 and 32.

Also, the LED element 1 is bonded on the submount substrate 2 (the p-side wiring pattern layer 21) having the burrs BR as illustrated in FIG. 4C, and then, a thermal-pressuring process is carried out, so that only a top part of the burrs BR is dissolved as illustrated in FIG. 4D. However, as there is a pressure gradient of the LED element 1 (the p-side electrode 11-6), the amount of the AuSn eutectic bonding layer 31′-1, 31′-2, . . . , 31′-6 and 32′ would be uneven. As a result, the AuSn eutectic bonding layer 31′-1, 31′-2, . . . , 31′-6 and 32′ would become uneven to create a large gap G between the LED element 1 (the p-side electrode 11-6) and the submount substrate 2 (the p-side wiring pattern layer 21). That is, only apart of the LED element 1 (the p-side electrode 11-6) can be in contact with the submount substrate 2 (the p-side wiring pattern layer 21), so that the bonding area therebetween would be small. Even when the LED element 1 (the p-side electrode 11-6) is completely in contact with the submount substrate 2 (the p-side wiring pattern layer 21), AuSn would be exposed to a high temperature due to the presence of the burrs BR, and would be thermally oxidized before the burrs BR are dissolved, which would be an obstacle in a eutectic reaction. Thus, a defective bonding would happen between the LED element 1 and the submount substrate 2 after the thermal-pressuring process.

Further, since the p-side electrodes 11-1, 11-2, . . . , 11-6 and the n-side electrode 12 and their corresponding AuSn layers 31-1, 31-2, . . . , 31-6 and 32 are slender, the AuSn layers 31-1, 31-2, . . . , 31-6 and 32 would be sloped lengthwise as illustrated in FIG. 5A, or the center portions of the AuSn layers 31-1, 31-2, . . . , 31-6 and 32 would be deeply concave as illustrated in FIG. 5B, or the center portions of the AuSn layers 31-1, 31-2, . . . , 31-6 and 32 would be highly convex as illustrated in FIG. 5C. In any case, the bonding area between the LED element 1 and the submount substrate 2 would be decreased, so that a defective bonding also would happen between the LED element 1 and the submount substrate 2 after the thermal-pressuring process.

The above-described defective bonding would invite the fluctuation of the heat resistance and the fluctuation of the forward voltage, which would invite irregular light emitting characteristics.

Still further, when the burrs BR are created on the edges of the AuSn layers 31-1, 31-2, . . . , 31-6 and 32, or the AuSn layers 31-1, 31-2, . . . , 31-6 and 32 are sloped lengthwise, deeply concave or highly convex, the AuSn eutectic bonding layer 31′-1, 31′-2, . . . , 31′-6 and 32′ after the thermal-pressuring process would protrude from the LED element 1 as illustrated by X in FIGS. 6A and 6B. Particularly, when the AuSn layers 31-1, 31-2, . . . , 31-6 and 32 are sloped lengthwise, the LED element 1 would be sloped as illustrated in FIG. 6B. As a result, the LED element 1 would be short-circuited to the wiring pattern layer 21 or 22 of the submount substrate 2, so that the semiconductor light emitting apparatus 3 would not operate.

### SUMMARY

The presently disclosed subject matter seeks to solve one or more of the above-described problems.

According to the presently disclosed subject matter, a semiconductor light emitting apparatus includes a semiconductor light emitting element having a first electrode and a second electrode, a substrate having first and second wiring pattern layers electrically-connected to the first and second electrodes, respectively, and multiple conductive bonding layer elements provided between the first electrode and the first wiring pattern layer and/or between the second electrode and the second wiring pattern layer.

A method for manufacturing a semiconductor light emitting apparatus includes preparing a semiconductor light emitting element having a first electrode and a second electrode, preparing a substrate having first and second wiring pattern layers electrically-connected to the first and second electrodes, respectively, forming multiple conductive bonding layer elements on one of the first electrode and the first wiring pattern layer and/or between the second electrode and the second wiring pattern layer, and carrying out a thermal-pressuring process to bond the first electrode to the first wiring pattern layer and bond the second electrode to the second wiring pattern layer.

According to the presently disclosed subject matter, a bonding defect between the semiconductor light emitting element and the substrate can be substantially eliminated.

### BRIEF DESCRIPTION OF THE DRAWINGS

The above and other advantages and features of the presently disclosed subject matter will be more apparent from the following description of certain embodiments, compared with the prior art, taken in conjunction with the accompanying drawings, wherein:

FIGS. 1A, 2A and 3A are top views for explaining a prior art method for manufacturing a semiconductor light emitting apparatus;

FIGS. 1B, 2B and 3B are cross-sectional views taken along the line B-B of FIGS. 1A, 2A and 3A, respectively;

FIGS. 4A, 4B, 4C and 4D are cross-sectional views for explaining a problem caused by the prior art method as illustrated in FIGS. 1A, 1B, 2A, 2B, 3A and 3B;

FIGS. 5A, 5B and 5C are cross-sectional views for explaining another problem caused by the prior art method as illustrated in FIGS. 1A, 1B, 2A, 2B, 3A and 3B;

FIG. 6A is a top view for explaining still another problem caused by the prior art method as illustrated in FIGS. 1A, 1B, 2A, 2B, 3A and 3B;

FIG. 6B is a cross-sectional view taken along the line B-B of FIG. 6A;

FIGS. 7A, 8A and 9A are top views for explaining a first embodiment of the method for manufacturing a semiconductor light emitting apparatus according to the presently disclosed subject matter;

FIGS. 7B, 8B and 9B are cross-sectional views taken along the line B-B of FIGS. 7A, 8A and 9A, respectively;

FIGS. 10A, 10B, 10C and 10D are cross-sectional views for explaining an effect caused by the method as illustrated in FIGS. 7A, 7B, 8A, 8B, 9A and 9B;

FIGS. 11A, 11B and 11C are cross-sectional views for explaining another effect caused by the method as illustrated in FIGS. 7A, 7B, 8A, 8B, 9A and 9B;

FIGS. 12A and 12B are a top view and a cross-sectional view illustrating a modification of the submount substrate of FIGS. 8A and 8B;

FIGS. 13A, 13B and 13C are cross-sectional views for explaining a method for manufacturing the submount substrate of FIGS. 12A and 12B;

FIGS. 14A, 15A and 16A are top views for explaining a second embodiment of the method for manufacturing a semiconductor light emitting apparatus according to the presently disclosed subject matter;

FIGS. 14B, 15B and 16B are cross-sectional views taken along the line B-B of FIGS. 14A, 15A and 16A, respectively;

FIG. 17A is a top view for explaining an effect caused by the method as illustrated in FIGS. 14A, 14B, 15A, 15B, 16A and 16B;

FIG. 17B is a cross-sectional view taken along the line B-B of FIG. 17A;

FIG. 18A is a top view for explaining an effect caused by a comparative example;

FIG. 18B is a cross-sectional view taken along the line B-B of FIG. 18A;

FIGS. 19A and 19B are a top view and a cross-sectional view illustrating a modification of the submount substrate of FIGS. 15A and 15B; and

FIGS. 20A and 20B are cross-sectional views for illustrating a modification of the AuSn layers of FIGS. 7A and 8B.

### DETAILED DESCRIPTION OF EXEMPLARY EMBODIMENTS

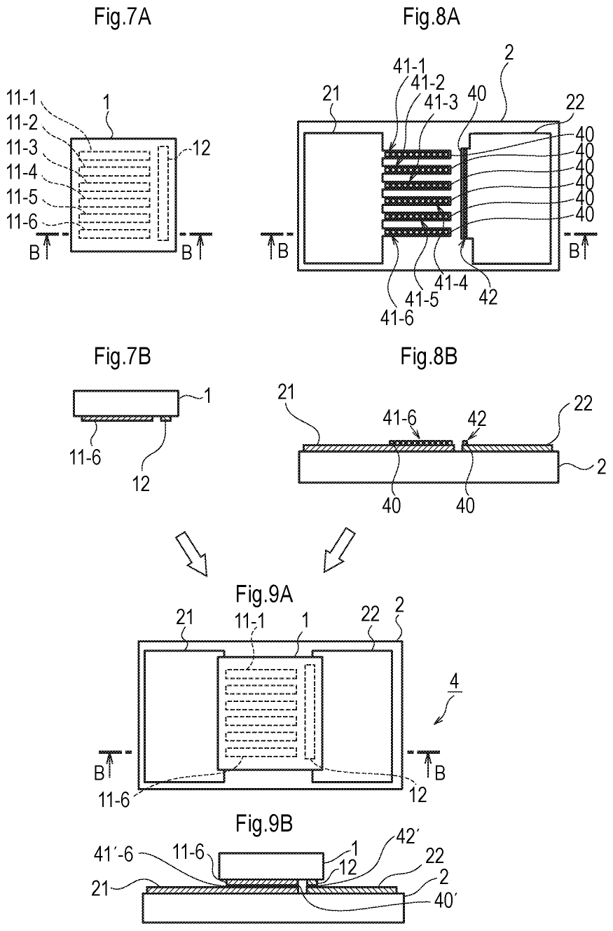

A first embodiment of the method for manufacturing a semiconductor light emitting apparatus will be explained now with reference to FIGS. 7A, 7B, 8A, 8B, 9A and 9B.

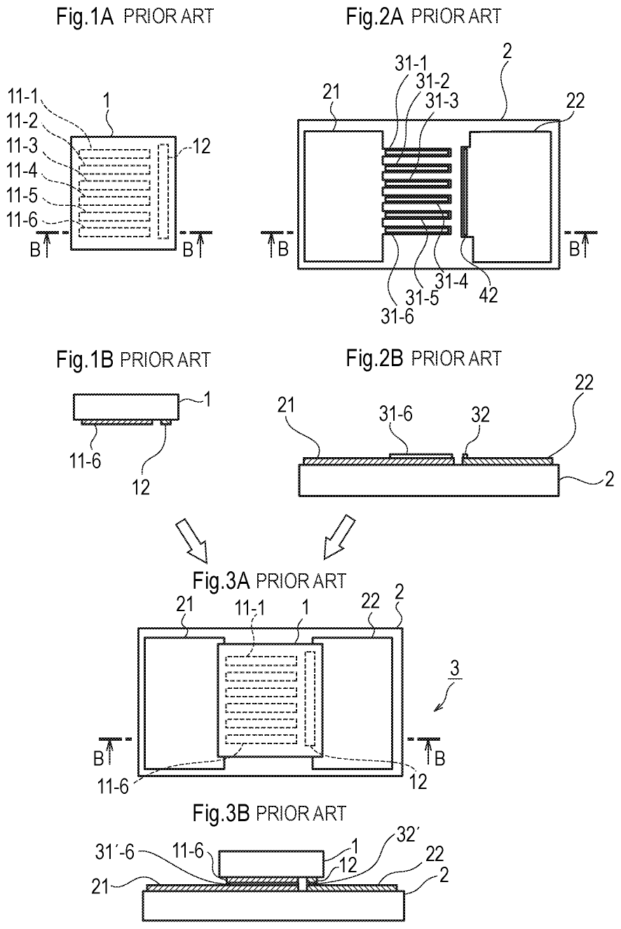

First, referring to FIG. 7A and FIG. 7B which is a cross-sectional view taken along the line BB in FIG. 7A, an LED element 1 the same as illustrated in FIGS. 1A and 1B is provided.

On the other hand, referring to FIG. 8A and FIG. 8B which is a cross-sectional view taken along the line BB in FIG. 8A, a submount substrate 2 made of AlN, for example, has a p-side wiring pattern layer 21 and an n-side wiring pattern layer 22. The p-side wiring pattern layer 21 has AuSn layers 41-1, 41-2, . . . , 41-6 corresponding to the p-side electrodes 11-1, 11-2, . . . , 11-6, respectively, of the LED element 1, and the n-side wiring pattern layer 22 has an AuSn layer 42 corresponding to the n-side electrode 12 of the LED element 1. Each of the AuSn layers 41-1, 41-2, . . . , 41-6 and 42 is constructed by a series of about 1 to 5 μm thick discrete AuSn layer elements 40 which are one-dimensionally arranged. For example, each of the AuSn layer elements 40 is square viewed from the top, and has a side whose length is the same as the short side of the electrodes 11-1, 11-2, . . . , 11-6 and 12 of the LED element 1. In this case, the spacing between the AuSn layer elements 40 is preferably as small as possible.

Finally, referring to FIG. 9A and FIG. 9B which is a cross-sectional view taken along the line B-B in FIG. 9A, the LED element 1 of FIGS. 7A and 7B is faced down in a thermal-pressuring process on the submount substrate 2 of FIGS. 8A and 8B, so that the uppermost Au layers of the AuSn layer 41-1, 41-2, . . . , 41-6 and 42 of the submount substrate 2 are eutectic with the uppermost Au layers of the p-side electrodes 11-1, 11-2, . . . , 11-6 and the n-side electrode 12 of the LED element 1 to form AuSn eutectic bonding layers 41′-1, 41′-2, . . . , 41′-6 and 42′ each formed by multiple AuSn eutectic layer elements 40′. As a result, the p-side electrodes 11-1, 11-2, . . . , 11-6 of the LED element 1 are electrically connected to the p-side wiring pattern layer 21 of the submount substrate 2, and the n-side electrode 12 of the LED element 1 is electrically connected to the n-side wiring pattern layer 22 of the submount substrate 2. Thus, the LED element 1 is bonded by the AuSn eutectic bonding layers 41′-1, 41′-2, . . . , 41′-6 and 42′ to the submount substrate 2, completing a semiconductor light emitting apparatus 4.

In the semiconductor light emitting apparatus 4 of FIGS. 9A and 9B, however, the AuSn eutectic bonding layers 41′-1, 41′-2, . . . , 41′-6 and 42′ can avoid bonding defects.

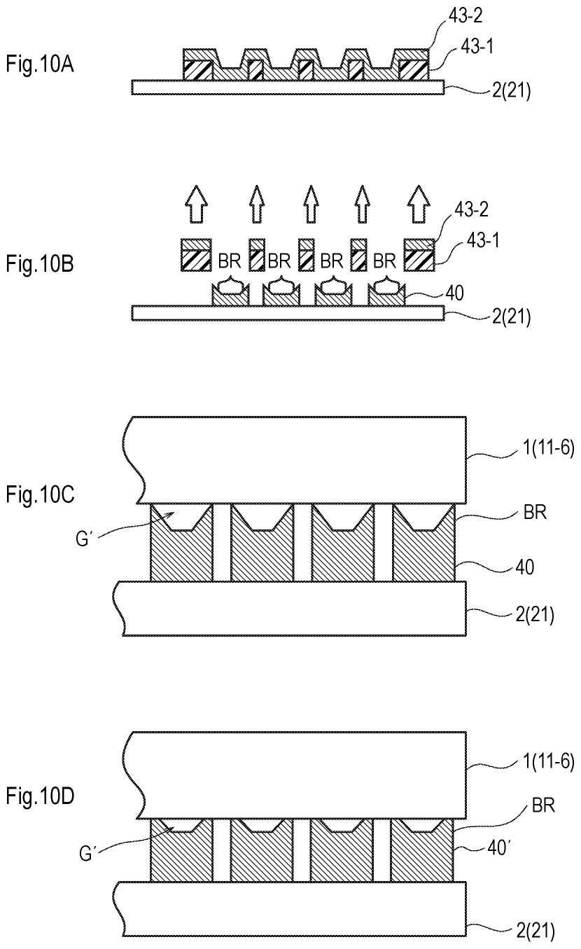

The AuSn layer elements 40 of the AuSn layers 41-1, 41-2, . . . , 41-6 and 42 of FIGS. 8A and 8B are formed by a liftoff process. That is, as illustrated in FIG. 10A, a photoresist pattern 43-1 for forming the AuSn layers 41-1, 41-2, . . . , 41-6 and 42 is formed by a photolithography process on a submount substrate 2 (the p-side wiring pattern layer 21), and then, an about 1 to 5 μm thick AuSn layer 43-2 is deposited on the entire surface by a sputtering process or an evaporating process. Then, as illustrated in FIG. 10B, the photoresist pattern layer 43-1 is removed to form the AuSn layer elements 40 of the AuSn layers 41-1, 41-2, . . . , 41-6 and 42. Even in this case, when the photoresist pattern layer 43-1 is removed to rupture the AuSn layer 43-2, burrs BR would be created on the edges of the AuSn layer elements 40 of the AuSn layers 41-1, 41-2, . . . , 41-6 and 42.

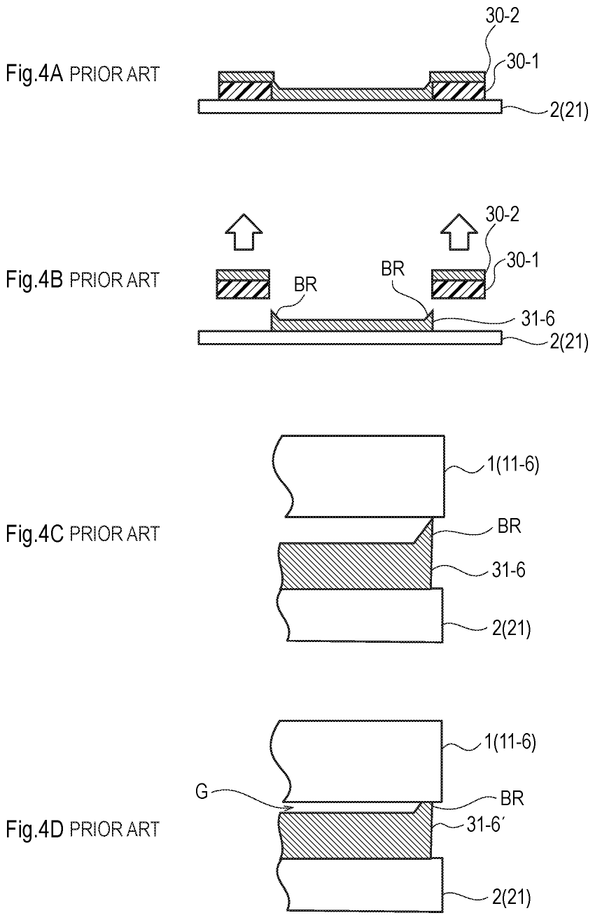

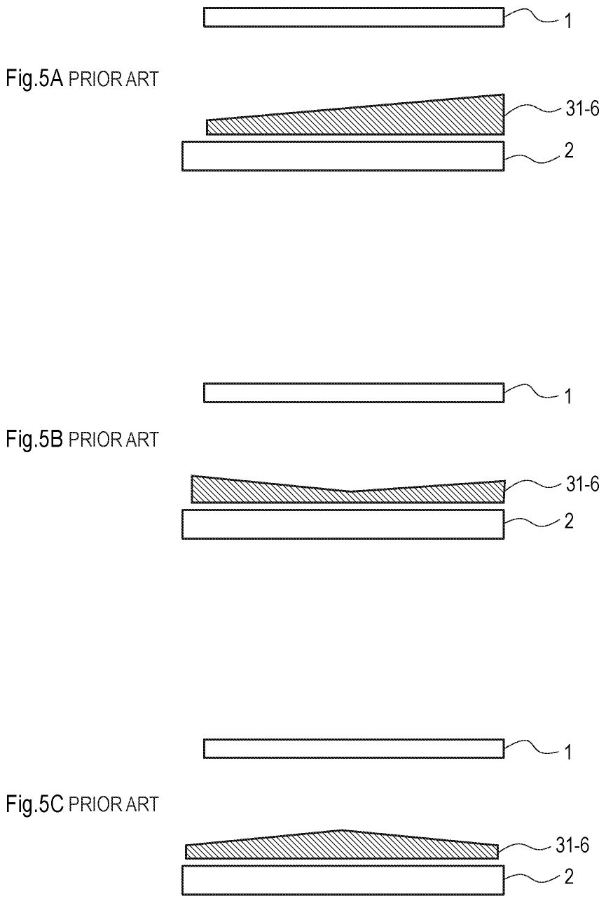

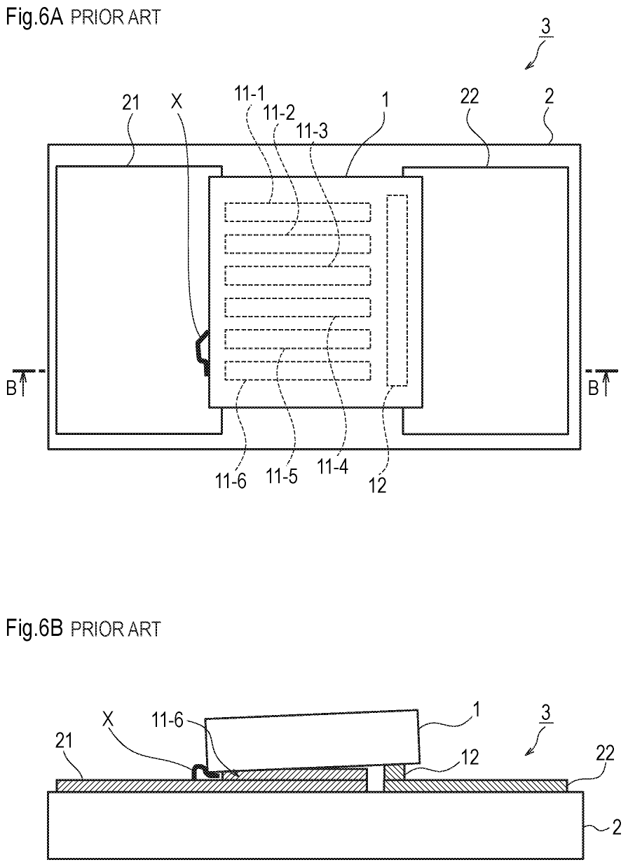

Also, the LED element 1 is bonded on the submount substrate 2 (the p-side wiring pattern layer 21) having the burrs BR as illustrated in FIG. 10C, and then, a thermal-pressuring process is carried out, so that only a top part of the burrs BR is dissolved as illustrated in FIG. 10D. Also, as there is a pressure gradient of the LED element 1 (the p-side electrode 11-6), the amount of the AuSn eutectic bonding layer elements 40′ would be uneven. As a result, the AuSn eutectic layer elements 40′ of the AuSn eutectic bonding layer 41′-1, 41′-2, . . . , 41′-6 and 42′ would become uneven to create a small gap G′ between the LED element 1 and the submount substrate 2. That is, only a part of the LED element 1 (the p-side electrode 11-6) can be in contact with the submount substrate 2, so that the bonding area therebetween would be small. Even when the LED element 1 is completely in contact with the submount substrate 2, AuSn would be exposed to a high temperature due to the presence of the burrs BR, and thermally oxidized before the burrs BR are dissolved, which would be an obstacle in a eutectic reaction. However, since each of the AuSn layer elements 40′ of FIG. 10C is much smaller than the AuSn layer 31-1, 31-2, . . . , 31-6 and 32 of FIG. 4C, the gap G′ of FIG. 10D is much smaller than the gap G of FIG. 4D. Therefore, the unbonded AuSn eutectic bonding layer elements 40′ can be decreased to substantially increase the bonding area of the AuSn eutectic bonding layer elements 40′. Thus, a defective bonding would hardly happen between the LED element 1 and the submount substrate 2 after the thermal-pressuring process.

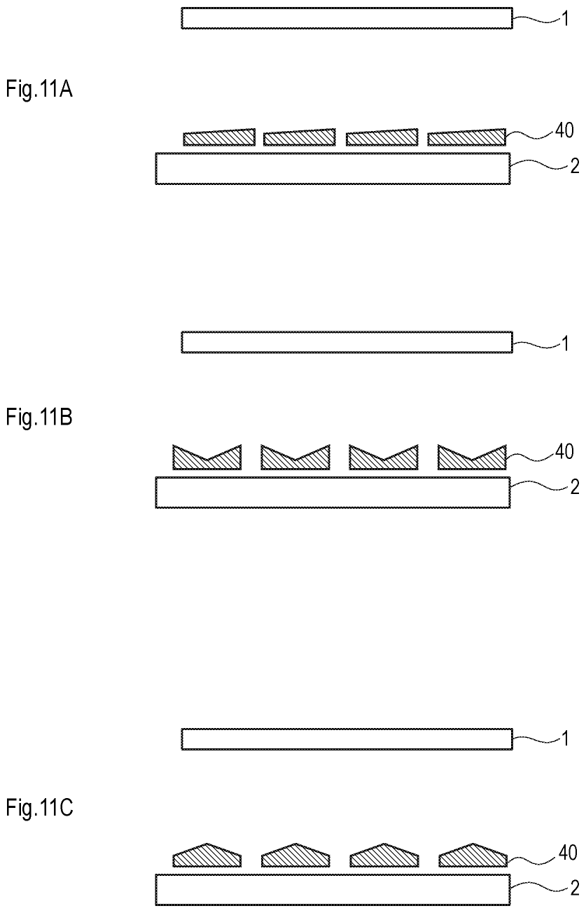

Further, although the p-side electrodes 11-1, 11-2, . . . , 11-6 and the n-side electrode 12 are slender, since the AuSn layer elements 40 are short, the AuSn layer elements 40 would be not sloped lengthwise as illustrated in FIG. 11A, or the center portions of the AuSn layer elements 40 would be shallowly concave as illustrated in FIG. 11B, or the center portions of the AuSn layer elements 40 would be slightly convex as illustrated in FIG. 11C. In any case, the bonding area between the LED element 1 and the submount substrate 2 would be increased, so that a defective bonding would hardly happen between the LED element 1 and the submount substrate 2 after the thermal-pressuring process.

Thus, the fluctuation of the heat resistance and the fluctuation of the forward voltage can be improved, which would also improve the light emitting characteristics.

Still further, since the burrs BR created on the edges of the AuSn layers 41-1, 41-2, . . . , 41-6 and 42 are small, or the AuSn layers 41-1, 41-2, . . . , 41-6 and 42 are not sloped lengthwise, shallowly concave or slightly convex, the AuSn eutectic bonding layers 41′-1, 41′-2, . . . , 41′-6 and 42′ after the thermal-pressuring process would hardly be protruded from the LED element 1. In addition, since the burrs BR of the AuSn layers 41-1, 41-2, . . . , 41-6 and 42 are small, the LED element 1 would not be sloped. As a result, the LED element 1 would not be short-circuited to the p-side wiring pattern layer 21 or 22 of the submount substrate 2, so that the semiconductor light emitting apparatus 4 would operate.

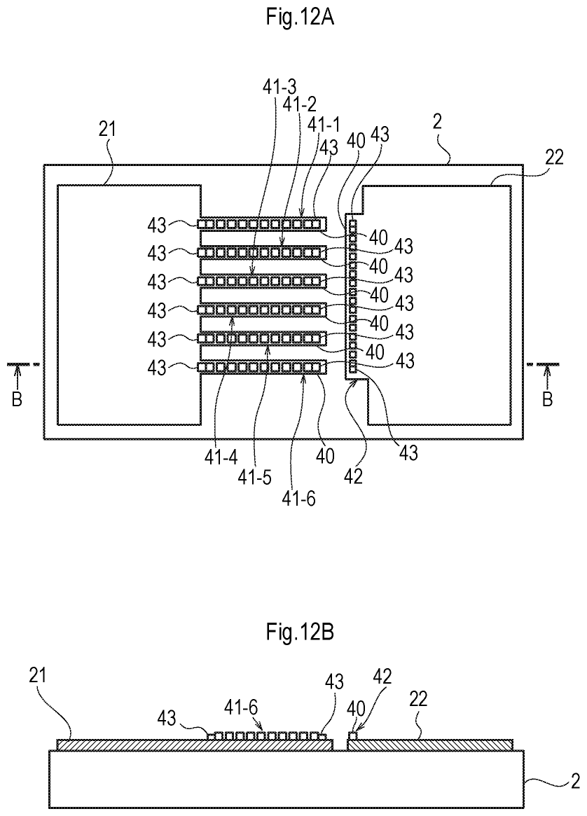

FIG. 12A is a top view illustrating a modification of the submount substrate 2 of FIGS. 8A and 8B, and FIG. 12B is a cross-sectional view taken along the line B-B in FIG. 12A.

In FIGS. 12A and 12B, AuSn-phobic Cr layers 43 that lack an affinity to repel AuSn are provided adjacent to the ends of the series of the AuSn layer elements 40. Therefore, in a thermal-pressuring process, the AuSn eutectic bonding layers 41′-1, 41′-2, . . . , 41′-6 and 42′ move away from the Cr layers 43, thus surely preventing the AuSn eutectic bonding layers 41′-1, 41′-2, . . . , 41′-6 and 42′ from protruding from the LED element 1 after the thermal-pressuring process.

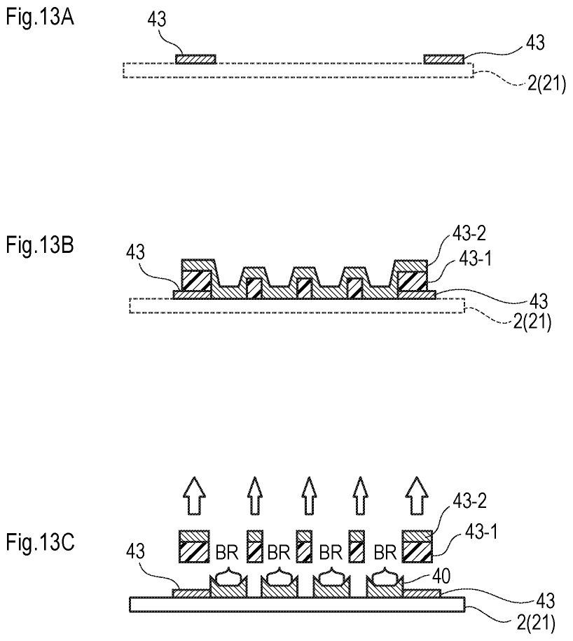

The Cr layers 43 are formed before the formation of the AuSn layer elements 40. That is, as illustrated in FIG. 13A, an about 0.1 μm thick Cr layer 43 is formed on the p-side wiring pattern layers 21 and 22 of the submount substrate 2 by a plating process and a photolithography and etching process. After that, the AuSn layer elements 40 of the AuSn layers 41-1, 41-2, . . . , 41-6 and 42 are formed by a liftoff process. That is, as illustrated in FIG. 13B, a photoresist pattern 43-1 for forming the AuSn layers 41-1, 41-2, . . . , 41-6 and 42 is formed by a photolithography process on a submount substrate 2 (the p-side wiring pattern layer 21), and then, an about 1 to 5 μm thick AuSn layer 43-2 is deposited on the entire surface by a sputtering process or a vacuum depositing process. Then, as illustrated in FIG. 13C, the photoresist pattern layer 43-1 is removed to form the AuSn layer elements 40 of the AuSn layers 41-1, 41-2, . . . , 41-6 and 42. Even in this case, when the photoresist pattern layer 43-1 is removed to rupture the AuSn layer 43-2, small burrs BR would be created on the edges of the AuSn layer elements 40 of the AuSn layers 41-1, 41-2, . . . , 41-6 and 42.

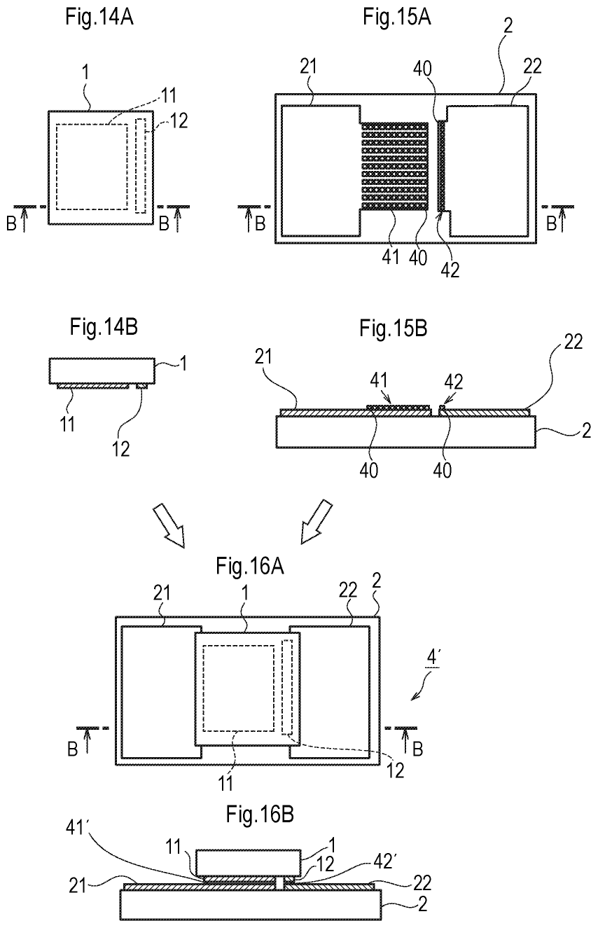

A second embodiment of the method for manufacturing a semiconductor light emitting apparatus will be explained now with reference to FIGS. 14A, 14B, 15A, 15B, 16A and 16B.

First, referring to FIG. 14A and FIG. 14B which is a cross-sectional view taken along the line BB in FIG. 14A, one broad p-side electrode 11 is provided instead of the p-side electrodes 11-1, 11-2, . . . , 11-6 of FIGS. 7A and 7B.

On the other hand, referring to FIG. 15A and FIG. 15B which is a cross-sectional view taken along the line BB in FIG. 8A, provided on the p-side wiring pattern layer 21 is an AuSn layer 41 corresponding to the p-side electrode 11 of the LED element 1. The AuSn layer 41 is constructed by about 1 to 5 μm thick discrete AuSn layer elements 40 which are two-dimensionally arranged. Also, in this case, each of the AuSn layer elements 40 is square viewed from the top, and the spacing between the AuSn layer elements 40 is preferably as small as possible.

Finally, referring to FIG. 16A and FIG. 16B which is a cross-sectional view taken along the line B-B in FIG. 16A, the LED element 1 of FIGS. 14A and 14B is faced down in a thermal-pressuring process on the submount substrate 2 of FIGS. 15A and 15B, so that the uppermost Au layers of the AuSn layer elements 40 of the AuSn layers 41 and 42 of the submount substrate 2 are eutectic with the uppermost Au layers of the p-side electrode 11 and the n-side electrode 12 of the LED element 1 to form AuSn eutectic bonding layers 41′ and 42′ each formed by multiple AuSn eutectic layer elements 40′. As a result, the p-side electrode 11 of the LED element 1 is electrically connected to the p-side wiring pattern layer 21 of the submount substrate 2, and the n-side electrode 12 of the LED element 1 is electrically connected to the n-side wiring pattern layer 22 of the submount substrate 2. Thus, the LED element 1 is bonded by the AuSn eutectic bonding layers 41′ and 42′ to the submount substrate 2, completing a semiconductor light emitting apparatus 4′.

Even in the semiconductor light emitting apparatus 4′ of FIGS. 16A and 16B, since the bonding defects of the AuSn eutectic bonding layers 41′ and 42′ can be dissolved, the fluctuation of the heat resistance and the fluctuation of the forward voltage can be improved, which would also improve the light emitting characteristics.

Also, since the burrs BR created on the edges of the AuSn layers 41 and 42 are small, or the AuSn layers 41 and 42 are not sloped lengthwise, shallowly concave or slightly convex, the AuSn eutectic bonding layer 41′-1, 41′-2, . . . , 41′-6 and 42′ after the thermal-pressuring process would hardly be protruded from the LED element 1. In addition, since the burrs BR of the AuSn layers 41-1, 41-2, . . . , 41-6 and 42 are small, the LED element 1 would not be sloped. As a result, the LED element 1 would not be short-circuited to the wiring pattern layer 21 or 22 of the submount substrate 2, so that the semiconductor light emitting apparatus 4 would operate.

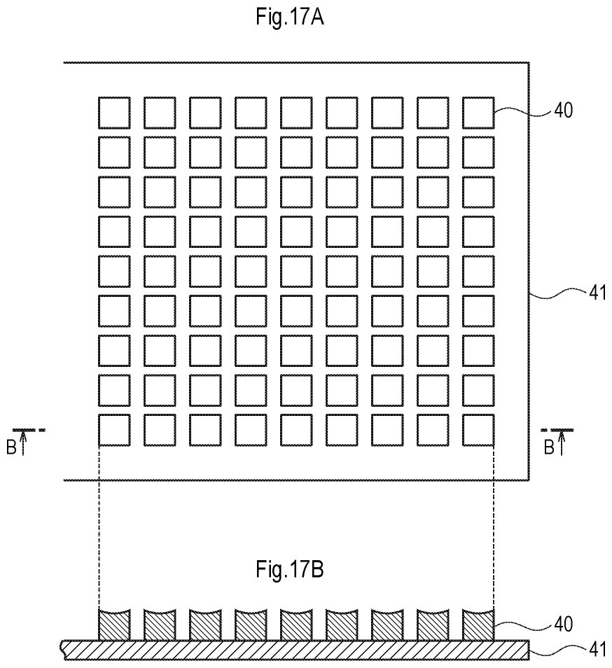

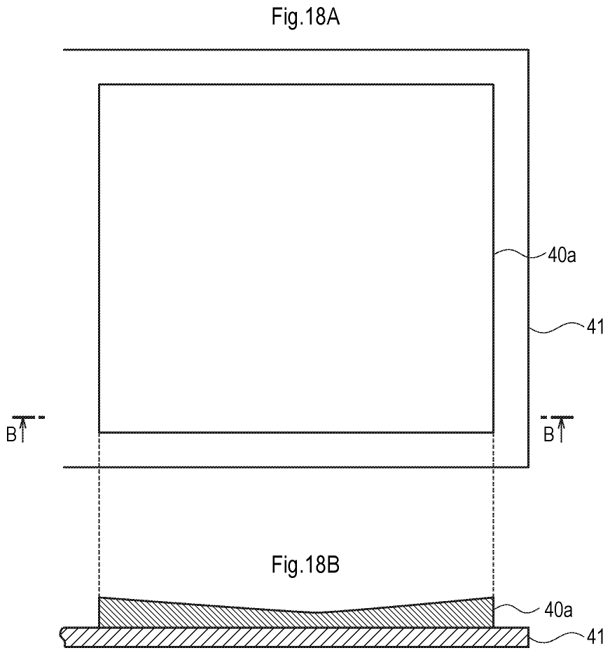

For example, as illustrated in FIGS. 17A and 17B, each of the AuSn layer elements 40 is shallowly concave. Contrary to this, if the AuSn layer elements 40 are constructed by a single AuSn layer element 40a as illustrated in FIGS. 18A and 18B, the single AuSn layer element 40a is greatly concave.

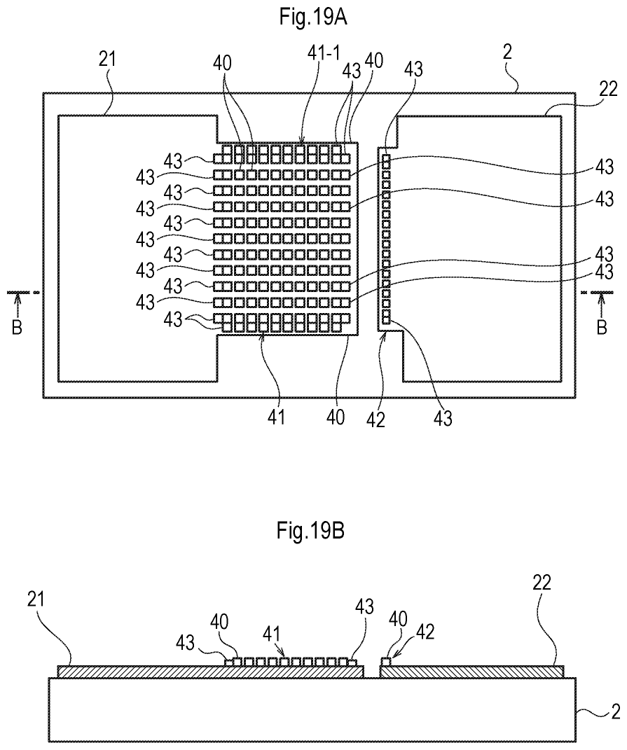

FIG. 19A is a top view illustrating a modification of the submount substrate 2 of FIGS. 15A and 15B, and FIG. 19B is a cross-sectional view taken along the line B-B in FIG. 19A.

In FIGS. 19A and 19B, AuSn-phobic Cr layers 43 that lack an affinity to repel AuSn are provided adjacent to the ends of the rows and columns of the AuSn layer elements 40. Therefore, in a thermal-pressuring process, the AuSn eutectic bonding layers 41′ and 42′ move away from the Cr layers 43, thus surely preventing the AuSn eutectic bonding layers 41′ and 42′ from protruding from the LED element 1 after the thermal-pressuring process.

The Cr layers 43 are formed before the formation of the AuSn layer elements 40 in the same way as in FIGS. 13A, 13B and 13C.

In the above-described embodiments, the conductive bonding elements can be provided only between the p-side electrodes 11-1, 11-2, . . . , 11-6 of the LED element 1 and the p-side wiring pattern layer 21 of the submount substrate 2, or the conductive bonding elements can be provided only between the n-side electrode 12 of the LED element 1 and the n-side wiring pattern layer 22 of the submount substrate 2.

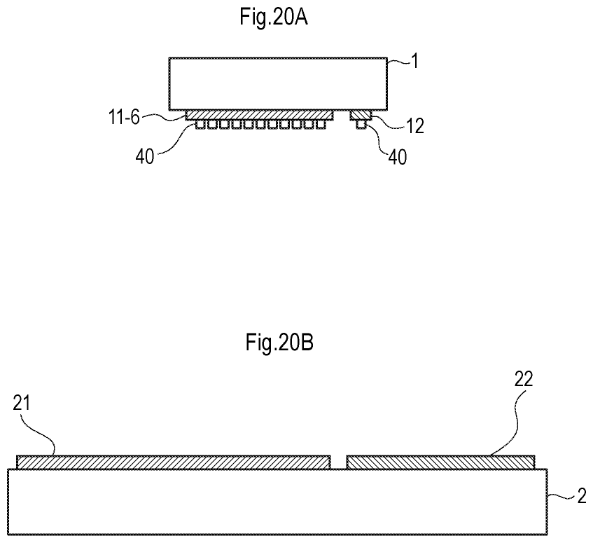

Also, in the above-described embodiments, the AuSn layer elements 40 are provided on the wiring pattern layers 21 and 22 of the submount substrate 2; however, as illustrated in FIGS. 20A and 20B, the AuSn layer elements 40 can be provided on the p-side electrodes 11-1, 11-2, . . . , 11-6 (or 11) and the n-side electrode 12 of the LED element 1. Also, the AuSn layer elements 40 can be formed by a screen printing process other than a lift-off process.

In addition, in the above-described embodiments, the LED element 1 and the submount substrate 2 are bonded by AuSn eutectic bonding layer elements 40′; however, the LED element 1 and the submount substrate 2 are bonded by other conductive bonding elements such as Ag particle sintered elements or Au particle sintered elements. In this case, Ag-phobic layers that lack an affinity to repel Ag or Au-phobic layers that lack an affinity to repel Au can be used instead of the Cr layers 43.

Further, the LED element 1 can be bonded directly to a conventional substrate without the submount substrate 2.

Still further, other semiconductor light emitting elements such as a laser diode (LD) element can be used instead of the LED element 1.

The semiconductor light emitting apparatus according to the presently disclosed subject matter can be applied to an ultraviolet light emitting apparatus, particularly, to a deep ultraviolet light emitting apparatus.

It will be apparent to those skilled in the art that various modifications and variations can be made in the presently disclosed subject matter without departing from the spirit or scope of the presently disclosed subject matter. Thus, it is intended that the presently disclosed subject matter covers the modifications and variations of the presently disclosed subject matter provided they come within the scope of the appended claims and their equivalents. All related or prior art references described above and in the Background section of the present specification are hereby incorporated in their entirety by reference.

1. A semiconductor light emitting apparatus comprising:
a semiconductor light emitting element having a first electrode and a second electrode;
a substrate having first and second wiring pattern layers electrically-connected to said first and second electrodes, respectively; and
multiple conductive bonding layer elements provided between said first electrode and said first wiring pattern layer and/or between said second electrode and said second wiring pattern layer.

2. The semiconductor light emitting apparatus as set forth in claim 1, further comprising conductive bonding layer elements-phobic layers, that lack an affinity to repel said conductive bonding layer elements, adjacent to ends of said multiple conductive bonding layer elements.

3. The semiconductor light emitting apparatus as set forth in claim 1, wherein said multiple conductive bonding layer elements are one-dimensionally or two-dimensionally arranged.

4. The semiconductor light emitting apparatus as set forth in claim 1, wherein said first electrode is defined as multiple first electrodes,
said first and second electrodes being rectangular viewed from the top, and each of said first and second electrodes having a short side and a long side twice or more as long as said short side.

5. The semiconductor light emitting apparatus as set forth in claim 1, wherein said conductive bonding layer elements comprise AuSn eutectic bonding layer elements, Ag particle sintered elements or Au particle sintered elements.

6. The semiconductor light emitting apparatus as set forth in claim 1, wherein said first electrode comprises a p-side electrode, and wherein said second electrode comprises an n-side electrode.

7. A method for manufacturing a semiconductor light emitting apparatus comprising:
preparing a semiconductor light emitting element having a first electrode and a second electrode;
preparing a substrate having first and second wiring pattern layers electrically-connected to said first and second electrodes, respectively;
forming multiple conductive bonding layer elements on one of said first electrode and said first wiring pattern layer and/or between said second electrode and said second wiring pattern layer; and
carrying out a thermal pressuring process to bond said first electrode to said first wiring pattern layer and bond said second electrode to said second wiring pattern layer.

8. The method for manufacturing a semiconductor light emitting apparatus as set forth in claim 7, further comprising forming conductive bonding layer elements-phobic layers, that lack an affinity to repel said multiple conductive bonding layer elements, adjacent to ends of said multiple conductive bonding layer elements.

9. The method for manufacturing a semiconductor light emitting apparatus as set forth in claim 7, wherein said multiple conductive bonding layer elements are one-dimensionally or two-dimensionally arranged.

10. The method for manufacturing a semiconductor light emitting apparatus as set forth in claim 7, wherein said first electrode is defined as multiple first electrodes,
said first and second electrodes being rectangular viewed from the top, and each of said first and second electrodes having a short side and a long side twice or more as long as said short side.

11. The method for manufacturing a semiconductor light emitting apparatus as set forth in claim 7, wherein said conductive bonding layer elements comprise AuSn eutectic bonding layer elements, Ag particle sintered elements or Au particle sintered elements.

12. The method for manufacturing a semiconductor light emitting apparatus as set forth in claim 7, wherein said first electrode comprises a p-side electrode, and wherein said second electrode comprises an n-side electrode.
